(19) United States
(12) Patent Application Publication
(10) Pub. No.: US 2025/0159792 A1
(43) Pub. Date: May 15, 2025

(54) WATERPROOF AND SHOCKPROOF STRUCTURE OF FAN MODULE

(71) Applicant: DELTA ELECTRONICS, INC., Taoyuan City (TW)

(72) Inventors: Kuo-Tung HSU, Taoyuan City (TW); Jen-Bo HUANG, Taoyuan City (TW); Li-Han HUNG, Taoyuan City (TW)

(21) Appl. No.: 18/640,661

(22) Filed: Apr. 19, 2024

(30) Foreign Application Priority Data
Nov. 10, 2023 (CN) 202323031107.6

(51) Int. Cl. H05K 1/02; H01R 12/70; H01R 12/77; H01R 13/52

(52) U.S. Cl. CPC H05K 1/0201; H01R 12/7076; H01R 12/7082; H01R 12/771; H01R 13/5202; H05K 2201/064; H05K 2201/066

(57) ABSTRACT

A waterproof and shockproof structure of a fan module includes a shell, a waterproof rubber sealing ring and a connector module. The shell includes an opening and a flange. The flange is disposed in the opening, the waterproof rubber sealing ring is also disposed in the opening, and the connector module is installed in the waterproof rubber sealing ring, and is movably installed in the opening of the shell. The waterproof rubber sealing ring includes a first abutting portion, a first surrounding portion and a second abutting portion. The first surrounding portion is connected to the first abutting portion, the second abutting portion is connected to the first surrounding portion, and the first abutting portion, the first surrounding portion and the second abutting portion cover three surfaces of the flange of the shell.

### CROSS-REFERENCE TO RELATED APPLICATION

This application claims priority to China Application Serial Number 202323031107.6, filed Nov. 10, 2023, the disclosures of which are incorporated herein by reference in their entireties.

### BACKGROUND

### Field of Invention

The present disclosure relates to a waterproof structure. More particularly, the present disclosure relates to a waterproof structure of a fan module.

### Description of Related Art

In a traditional electronic device, a fan is first fixed on the electronic device, and the fan is then connected to the power supply equipment through a power connecting wire and a connector to provide power. Because the power connecting wire is flexible, the power connecting wire needs to be fixed on the electronic device with clips or the like to fix the power connecting wire so as to supply the power to the fan and control the fan.

However, a traditional fan is not suitable to automatically assemble on the electronic device due to the lack of a fixed and controllable shape of the power connecting wire.

Therefore, some manufacturers use hooks to fix the connectors of the fans on the electronic device in an automatic fan assembly line. However, when some of the hooks and connectors of the fans are used for automatic assembly, some of the hooks and connectors of the fans may lead to parts damage or machine interruption due to assembly tolerances so as to seriously affect the production yield and throughput of automatic fan assembly and increase the manufacturing cost.

Therefore, there is a need to provide a convenient and safe connector to improve the production yield and throughput of the electronic device for automatically assembling the connector on the electronic device so as to reduce the production cost of the electronic device and improve the reliability of the electronic device.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a waterproof and shockproof structure of a fan module able to conveniently install on a system device together with the fan module so as to provide auto-alignment, waterproof and shockproof functions.

To achieve these and other advantages and in accordance with the objective of the embodiments of the present invention, as the embodiment broadly describes herein, the embodiments of the present invention provides a waterproof and shockproof structure of a fan module includes a shell, a waterproof rubber sealing ring and a connector module. The shell includes an opening and a flange, and the flange is disposed in the opening. The waterproof rubber sealing ring is installed in the opening of the shell and the connector module is installed in the waterproof rubber sealing ring and is moveably installed in the opening of the shell.

In some embodiments, the waterproof rubber sealing ring includes a first abutting portion, a first surrounding portion and a second abutting portion. The first surrounding portion is connected to the first abutting portion and the second abutting portion is connected to the first surrounding portion. In addition, the first abutting portion, the first surrounding portion and the second abutting portion cover three surfaces of the flange of the shell.

In some embodiments, the waterproof and shockproof structure of the fan module further includes a fixing plate fixed on one side of the opening of the shell to allow the connector module movably contacting the fixing plate.

In some embodiments, the connector module includes a connector main body and an electric circuit board connected to the connector main body, and the fixing plate presses on a surface of the electric circuit board.

In some embodiments, the electric circuit board is a flexible printed circuit board.

In some embodiments, the waterproof rubber sealing ring further includes a second surrounding portion connected to the second abutting portion and contacting the shell, the electric circuit board and the fixing plate.

In some embodiments, the waterproof and shockproof structure of the fan module further includes a second waterproof rubber sealing ring disposed between the shell and the electric circuit board, and contacting the shell, the electric circuit board and the fixing plate.

In some embodiments, the connector module further includes a fan control circuit board connected to the electric circuit board to control a fan module.

In some embodiments, the shell further includes a concave recess to accommodate the fan module.

In some embodiments, the fixing plate is formed on a cover plate of the fan module.

In some embodiments, the waterproof rubber sealing ring includes a plurality of sealing ring protrusions abutting on a side surface of the connector main body of the connector module.

In some embodiments, the connector main body includes a plurality of connector protrusions abutting on the waterproof rubber sealing ring, and the sealing ring protrusions are perpendicular to the connector protrusions.

In another embodiment, a waterproof and shockproof structure of a fan module includes a shell, a first waterproof rubber sealing ring, a second waterproof rubber sealing ring and a connector module. The shell includes an opening and a flange, and the flange is disposed in the opening. The first waterproof rubber sealing ring is installed on one side of the opening, and the first waterproof rubber sealing ring includes an abutting portion and a surrounding portion connected to the abutting portion, and the abutting portion and the surrounding portion cover at least two surfaces of the flange. In addition, the second waterproof rubber sealing ring is installed on another side of the opening and the connector module is installed in the first waterproof rubber sealing ring and the second waterproof rubber sealing ring, and is installed in the opening.

In some embodiments, the waterproof and shockproof structure of the fan module further includes a fixing plate fixed on one side of the opening of the shell to allow the connector module movably contacting the fixing plate.

In some embodiments, the connector module includes a connector main body and an electric circuit board connected to the connector main body, and the fixing plate presses on a surface of the electric circuit board.

In some embodiments, the connector module further includes a fan control circuit board connected to the electric circuit board to control a fan module.

In some embodiments, the shell further includes a concave recess to accommodate the fan module.

In some embodiments, the first waterproof rubber sealing ring includes a plurality of sealing ring protrusions abutting on a side surface of the connector main body of the connector module.

In some embodiments, the connector main body includes a plurality of connector protrusions abutting on the first waterproof rubber sealing ring, and the sealing ring protrusions are perpendicular to the connector protrusions.

In some embodiments, the electric circuit board is a flexible printed circuit board.

Hence, the waterproof and shockproof structure according to the present invention may be conveniently installed on the system device together with the fan module, and provide automatic alignment, waterproof and shockproof functions to effectively increase the production yield and throughput of the electronic device while automatically installing the fan module on the electronic device so as to reduce the production cost of the electronic device and improve the quality of the electronic device.

### BRIEF DESCRIPTION OF THE DRAWINGS

The disclosure can be more fully understood by reading the following detailed description of the embodiment, with reference made to the accompanying drawings as follows:

FIG. 1 illustrates a schematic perspective diagram of a fan module having a waterproof and shockproof structure according to one embodiment of the present invention;

FIG. 2 illustrates a schematic perspective diagram of an electronic device equipped with the fan module having the waterproof and shockproof structure of FIG. 1;

FIG. 3 illustrates a partial enlargement diagram of a waterproof and shockproof structure of a fan module according to one embodiment of the present invention;

FIG. 4 illustrates a partial enlargement diagram of a waterproof and shockproof structure of a fan module according to another embodiment of the present invention; and

FIG. 5 illustrates a partial enlargement diagram of a waterproof rubber sealing ring of a waterproof and shockproof structure of a fan module according to some embodiments of the present invention.

### DETAILED DESCRIPTION

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

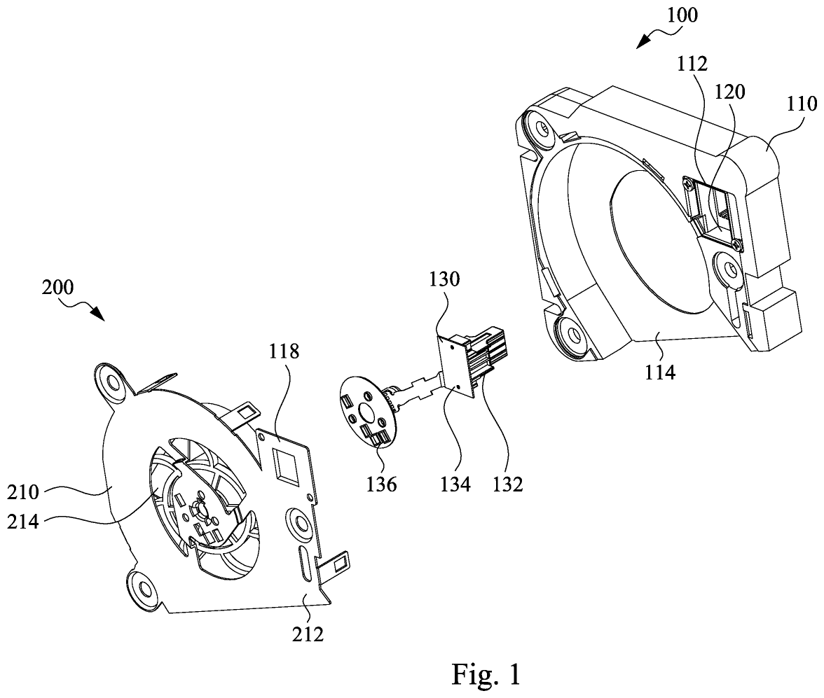

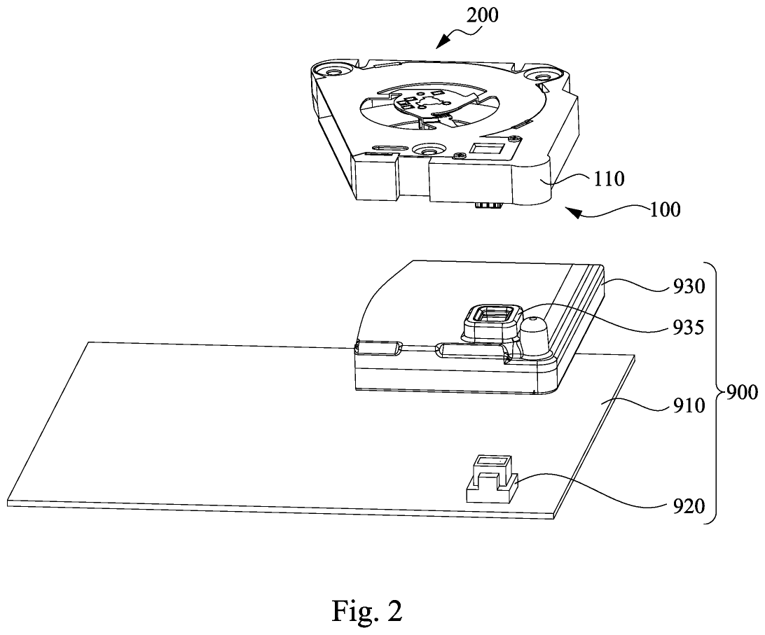

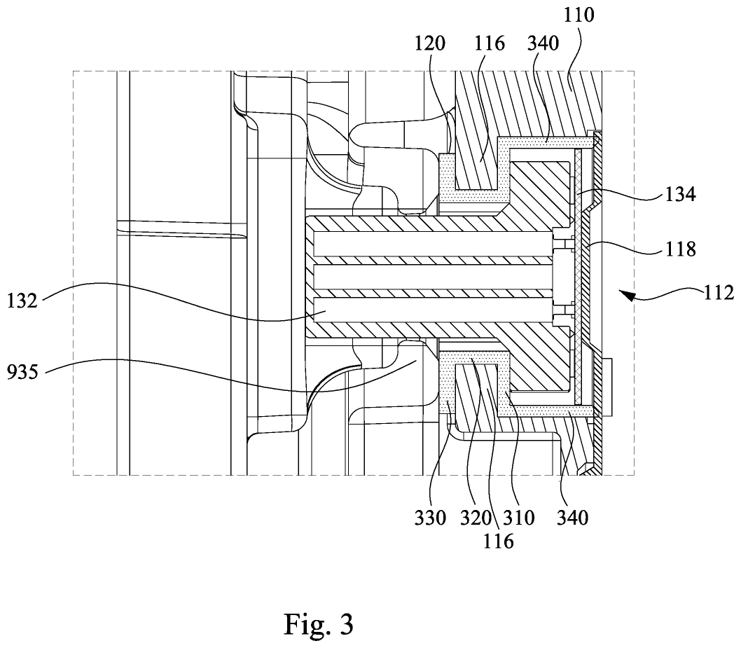

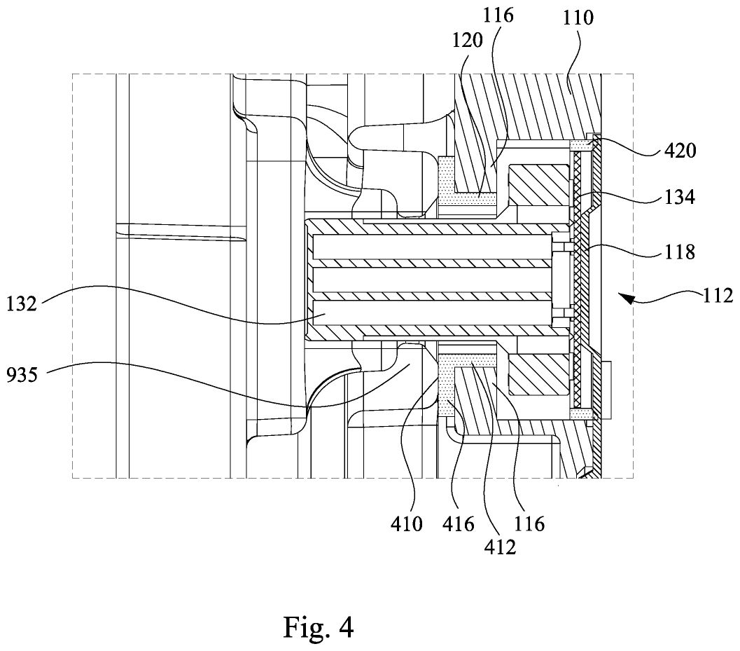

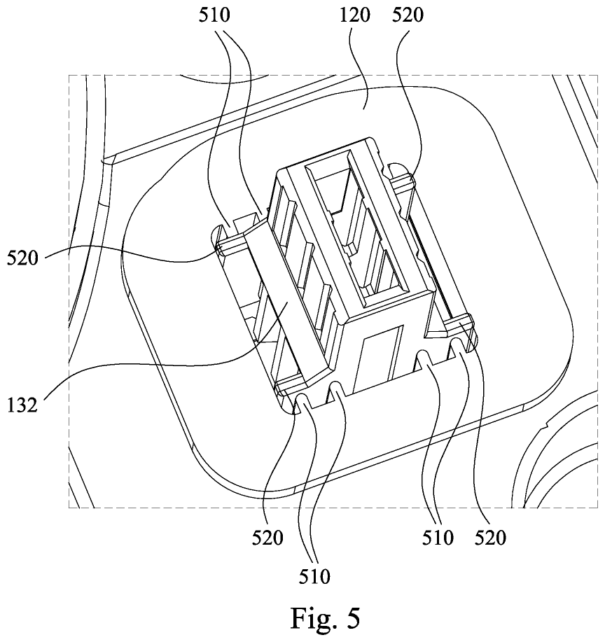

FIG. 1 illustrates a fan module having a waterproof and shockproof structure, FIG. 2 illustrates an electronic device equipped with the fan module having the waterproof and shockproof structure, FIG. 3 illustrates a partial enlargement diagram of the waterproof and shockproof structure of the fan module, FIG. 4 illustrates a partial enlargement diagram of the waterproof and shockproof structure of the fan module according to another embodiment of the present invention, and FIG. 5 illustrates a partial enlargement diagram of the waterproof rubber sealing ring of the waterproof and shockproof structure of the fan module.

First referring to FIG. 1 and FIG. 3, a waterproof and shockproof structure 100 of a fan module 200 includes a shell 110, a waterproof rubber sealing ring 120 and a connector module 130. The shell 110 includes an opening 112 and a flange 116, and the flange 116 is disposed in the opening 112. The waterproof rubber sealing ring 120 is installed in the opening 112, and the connector module 130 is installed in the waterproof rubber sealing ring 120, and the connector module 130 is moveably installed in the opening 112 of the shell 110 to provide an auto-alignment function for the connector module 130 and a waterproof and shockproof function for the waterproof and shockproof structure 100 of the fan module 200.

Referring to FIG. 2, as shown in the drawing, a system device 900 includes an electric circuit board 910, a system connector 920 and a waterproof shell 930. The waterproof shell 930 covers on one side of the electric circuit board 910, and the waterproof shell 930 includes a connecting boss 935 and the system connector 920 is exposed from the connecting boss 935. In addition, the fan module 200 is equipped with a waterproof and shockproof structure 100. Therefore, when a user installs the fan module 200 on the system device 900, the waterproof and shockproof structure 100 of the fan module 200 may automatically align to the system connector 920, and electrically connect to the system connector 920. At the moment, the waterproof rubber sealing ring 120 of the waterproof and shockproof structure 100 of the fan module 200 contacts the connecting boss 935 to prevent moisture from flowing between the fan module 200 and the electric circuit board 910.

Further referring to FIG. 3, in some embodiments, the waterproof rubber sealing ring 120 includes a first abutting portion 330, a first surrounding portion 320 and a second abutting portion 310. The first surrounding portion 320 is connected to the first abutting portion 330, for example, vertically or obliquely to the first abutting portion 330, without departing from the spirit and protection scope of the present invention. In addition, the second abutting portion 310 is connected to the first surrounding portion 320, for example, vertically or obliquely to the first surrounding portion 320, without departing from the spirit and protection scope of the present invention. In some embodiments, the first abutting portion 330 is used to contact the connecting boss 935 of the system device 900, but not limited thereto.

In some embodiments, the first abutting portion 330, the first surrounding portion 320 and the second abutting portion 310 cover the surfaces of the flange 116 of the shell 110, for example, cover three vertical surfaces of the flange 116 of the shell 110, but not limited thereto.

In some embodiments, the waterproof rubber sealing ring 120 further includes a second surrounding portion 340 to connect to the second abutting portion 310, for example, vertically or obliquely to the second abutting portion 310, without departing from the spirit and protection scope of the present invention.

In some embodiments, the waterproof and shockproof structure 100 of the fan module 200 further includes a fixing plate 118 fixed on one side of the opening 112 of the shell 110 to allow the connector module 130 movably contacting the fixing plate 118 and prevent the connector module 130 from moving perpendicular to the opening 112.

It is worth noting that the second surrounding portion 340 directly contacts the fixing plate 118 to further improve the waterproof capability of the waterproof and shockproof structure 100 of the fan module 200 to further prevent moisture from flowing between the fan module 200 and the electric circuit board 910.

In some embodiments, the connector module 130 includes a connector main body 132, an electric circuit board 134, e.g. a flexible printed circuit board, and a fan control circuit board 136. The electric circuit board 134 is connected to the connector main body 132, and the fixing plate 118 presses on the surface of the electric circuit board 134 to prevent the connector module 130 from moving perpendicular to the opening 112 and provide a contact pressure between the electric circuit board 134 and the connector main body 132 to reduce the chance of circuit breakage therebetween.

In some embodiments, the second surrounding portion 340 is connected to the second abutting portion 310, and contacts the shell 110, the electric circuit board 134 and the fixing plate 118.

The fan control circuit board 136, e.g. a rigid printed circuit board, is connected to the electric circuit board 134 to provide the power for the fan module 200, and control the rotational speed of the fan blade 214 of the fan module 200.

In some embodiments, the shell 110 further includes a concave recess 114 to accommodate the fan module 200 therein. In some embodiments, the shell 110 may be integrally formed with the shell of the fan module 200 to simultaneously assemble the fan module 200 and the waterproof and shockproof structure 100 to the system device 900.

In some embodiments, the fan module 200 includes a cover plate 210, and an air guiding portion 212 and the foregoing fixing plate 118 are formed on the cover plate 210 so that the connector module 130 may be stably installed in the waterproof rubber sealing ring 120 and the connector module 130 may be moveably installed in the opening 112 of the shell 110 when the fan module 200 is fixed on the shell 110.

Referring to FIG. 5, in some embodiments, the waterproof rubber sealing ring 120 includes a plurality of sealing ring protrusions 510 abutting on side surfaces of the connector main body 132 of the connector module 130 to provide a horizontal moving capability for the connector main body 132 of the connector module 130 able to move in the waterproof rubber sealing ring 120 so as to allow the connector main body 132 effectively maintaining in the center of the waterproof rubber sealing ring 120 without force thereon, and provide an elastic adjustment capability to allow the connector main body 132 aligning to the system connector 920 so that the production yield and throughput of the electronic device is increased while automatically installing the fan module 200 on the electronic device.

In some embodiments, the connector main body 132 includes a plurality of connector protrusions 520 abutting on inner sides of the waterproof rubber sealing ring 120, and the sealing ring protrusions 510 are preferably perpendicular to the connector protrusions 520 to provide a moving capability along another horizontal direction for the connector main body 132 of the connector module 130 able to move in the waterproof rubber sealing ring 120 so as to allow the connector main body 132 effectively maintaining in the center of the waterproof rubber sealing ring 120 without force thereon, and provide an elastic adjustment capability to allow the connector main body 132 aligning to the system connector 920 so that the production yield and throughput of the electronic device is increased while automatically installing the fan module 200 on the electronic device.

Referring to FIG. 4, another embodiment of the waterproof and shockproof structure 100 of the fan module 200 is illustrated. As shown in the drawing, the waterproof and shockproof structure 100 of the fan module 200 includes a shell 110, waterproof rubber sealing rings 120 and a connector module 130. The waterproof rubber sealing rings 120 include a first waterproof rubber sealing ring 410 and a second waterproof rubber sealing ring 420.

The shell 110 includes an opening 112 and a flange 116, and the flange 116 is disposed inside the opening 112. The first waterproof rubber sealing ring 410 is installed on one side of the opening 112, and the second waterproof rubber sealing ring 420 on another side of the opening 112. In addition, the connector module 130 is installed in the first waterproof rubber sealing ring 410 and the second waterproof rubber sealing ring 420. Furthermore, the connector module 130 is, for example, moveably installed in the opening 112 of the shell 110, but not limited thereto. In this embodiment, the first waterproof rubber sealing ring 410 and the second waterproof rubber sealing ring 420 may be formed independently and separated from each other, but not limited thereto.

In some embodiments, the first waterproof rubber sealing ring 410 includes an abutting portion 416 and a surrounding portion 412. The abutting portion 416 is, for example, abutted on the connecting boss 935 of the system device 900, and the surrounding portion 412 is connected to the abutting portion 416, for example, vertically or obliquely to the abutting portion 416, without departing from the spirit and protection scope of the present invention. Therefore, the abutting portion 416 and the surrounding portion 412 cover surfaces of the flange 116 of the shell 110, for example, at least two surfaces, but not limited thereto, so as to prevent moisture from flowing between the fan module 200 and the electric circuit board 910.

Similarly, in some embodiments, the waterproof and shockproof structure 100 of the fan module 200 further includes a fixing plate 118 fixed on one side of the opening 112 of the shell 110 to allow the connector module 130 movably contacting the fixing plate 118 to prevent the connector module 130 from moving perpendicular to the opening 112.

In addition, the connector module 130 also includes a connector main body 132, an electric circuit board 134, e.g. a flexible printed circuit board, and a fan control circuit board 136. The function and structure thereof are as explained above and will not be repeated here.

In some embodiments, the second waterproof rubber sealing ring 420 is disposed between the shell 110 and the electric circuit board 134, and contacts the shell 110, the electric circuit board 134 and the fixing plate 118.

In some embodiments, the shell 110 may be integrally formed with the shell of the fan module 200 to simultaneously install the fan module 200 and the waterproof and shockproof structure 100 on the system device 900. In addition, the fan module 200 is also equipped with a cover plate 210, and an air guiding portion 212 and a fixing plate 118 are formed on the cover plate 210, but not limited thereto.

In some embodiments, the first waterproof rubber sealing ring 410 of the waterproof rubber sealing ring 120 is preferably includes a plurality of sealing ring protrusions 510 abutting on side surfaces of the connector main body 132 of the connector module 130, and the connector main body 132 preferably includes a plurality of connector protrusions 520 abutting on the first waterproof rubber sealing ring 410 and the sealing ring protrusions 510 is perpendicular to the connector protrusions 520.

Accordingly, the waterproof and shockproof structure according to the present invention may be conveniently installed on the system device together with the fan module, and provide automatic alignment, waterproof and shockproof functions to effectively increase the production yield and throughput of the electronic device while automatically installing the fan module on the electronic device so as to reduce the production cost of the electronic device and improve the quality of the electronic device.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A waterproof and shockproof structure of a fan module, comprising:
a shell comprising an opening and a flange, wherein the flange is disposed in the opening;
a waterproof rubber sealing ring installed in the opening; and
a connector module installed in the waterproof rubber sealing ring and moveably installed in the opening of the shell, wherein the waterproof rubber sealing ring comprises:
a first abutting portion;
a first surrounding portion connected to the first abutting portion; and
a second abutting portion connected to the first surrounding portion, wherein the first abutting portion, the first surrounding portion and the second abutting portion cover three surfaces of the flange of the shell.

2. The waterproof and shockproof structure of the fan module of claim 1, further comprising:
a fixing plate fixed on one side of the opening of the shell to allow the connector module movably contacting the fixing plate.

3. The waterproof and shockproof structure of the fan module of claim 2, wherein the connector module comprises:
a connector main body; and
an electric circuit board connected to the connector main body, wherein the fixing plate presses on a surface of the electric circuit board.

4. The waterproof and shockproof structure of the fan module of claim 3, wherein the electric circuit board is a flexible printed circuit board.

5. The waterproof and shockproof structure of the fan module of claim 3, wherein the waterproof rubber sealing ring, further comprises:
a second surrounding portion connected to the second abutting portion, and contacting the shell, the electric circuit board and the fixing plate.

6. The waterproof and shockproof structure of the fan module of claim 3, further comprising:
a second waterproof rubber sealing ring disposed between the shell and the electric circuit board, and contacting the shell, the electric circuit board and the fixing plate.

7. The waterproof and shockproof structure of the fan module of claim 3, wherein the connector module, further comprises:
a fan control circuit board connected to the electric circuit board to control a fan module.

8. The waterproof and shockproof structure of the fan module of claim 7, wherein the shell further comprises a concave recess to accommodate the fan module.

9. The waterproof and shockproof structure of the fan module of claim 8, wherein the fixing plate is formed on a cover plate of the fan module.

10. The waterproof and shockproof structure of the fan module of claim 5, wherein the waterproof rubber sealing ring comprises:
a plurality of sealing ring protrusions abutting on a side surface of the connector main body of the connector module.

11. The waterproof and shockproof structure of the fan module of claim 10, wherein the connector main body comprises:
a plurality of connector protrusions abutting on the waterproof rubber sealing ring, wherein the sealing ring protrusions are perpendicular to the connector protrusions.

12. A waterproof and shockproof structure of a fan module, comprising:
a shell comprising an opening and a flange, wherein the flange is disposed in the opening;
a first waterproof rubber sealing ring installed on one side of the opening, wherein the first waterproof rubber sealing ring comprises:
an abutting portion; and
a surrounding portion connected to the abutting portion, wherein the abutting portion and the surrounding portion cover at least two surfaces of the flange;
a second waterproof rubber sealing ring installed on another side of the opening; and
a connector module installed in the first waterproof rubber sealing ring and the second waterproof rubber sealing ring, and installed in the opening.

13. The waterproof and shockproof structure of the fan module of claim 12, further comprising:
a fixing plate fixed on one side of the opening of the shell to allow the connector module movably contacting the fixing plate.

14. The waterproof and shockproof structure of the fan module of claim 13, wherein the connector module comprises:
a connector main body; and
an electric circuit board connected to the connector main body, wherein the fixing plate presses on a surface of the electric circuit board.

15. The waterproof and shockproof structure of the fan module of claim 14, wherein the connector module, further comprises:
a fan control circuit board connected to the electric circuit board to control a fan module.

16. The waterproof and shockproof structure of the fan module of claim 15, wherein the shell further comprises a concave recess to accommodate the fan module.

17. The waterproof and shockproof structure of the fan module of claim 14, wherein the first waterproof rubber sealing ring comprises:
a plurality of sealing ring protrusions abutting on a side surface of the connector main body of the connector module.

18. The waterproof and shockproof structure of the fan module of claim 17, wherein the connector main body comprises:
a plurality of connector protrusions abutting on the first waterproof rubber sealing ring, wherein the sealing ring protrusions are perpendicular to the connector protrusions.

19. The waterproof and shockproof structure of the fan module of claim 14, wherein the electric circuit board is a flexible printed circuit board.
